(19) United States
(12) Patent Application Publication
(10) Pub. No.: US 2025/0107377 A1
(43) Pub. Date: Mar. 27, 2025

(54) DISPLAY PANEL AND MANUFACTURING METHOD THEREFOR, AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Shuang LI, Beijing (CN); Taofeng XIE, Beijing (CN); Yulong WEI, Beijing (CN); Daiying ZHANG, Beijing (CN); Guanghua XU, Beijing (CN); Xiaodong CHU, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/728,038

(22) PCT Filed: Nov. 30, 2022
(86) PCT No.: PCT/CN2022/135394

§ 371 Date: Jul. 10, 2024

(51) Int. Cl. H10K 59/131; G06F 3/044; H10K 59/12; H10K 59/40

(52) U.S. Cl. CPC H10K 59/1315; G06F 3/0446; H10K 59/1201; H10K 59/40; G06F 2203/04103

(57) ABSTRACT

A display panel includes a display area (110) and a non-display area (120), wherein the non-display area (120) includes a first non-display area; a signal line layer (200) is arranged on a side of a base substrate (100); a touch layer (300) is arranged on a side of the signal line layer (200) away from the base substrate (100), and includes a plurality of touch lines (310), wherein, in at least part of the touch lines (310) in the first non-display area, a first touch line (311) and a second touch line (312) belonging to the same touch line (310) respectively have a first center line O1 and a second center line O2, and in a direction perpendicular to the extension of the touch line (310), the first center line O1 and the second center line O2 are not aligned.

### CROSS REFERENCE

The present application is the national phase application of International Application No. PCT/CN2022/135394, filed on Nov. 30, 2022, and the entire contents thereof are incorporated herein by reference for all purposes.

### TECHNICAL FIELD

The present disclosure relates to the field of display technology, and in particular to a display panel and a manufacturing method thereof, and a display device.

### BACKGROUND

At present, a flexible touch screen is formed by a Flexmeshlayeroncell (FMLOC) method. The touch layer included in the flexible touch screen is integrated on a flexible display substrate, and the touch layer is protected by an organic layer on the top. For OLED (Organic Light-Emitting Diode) touch screens, signal lines, such as data signal lines, are usually densely arranged in the peripheral area.

Information disclosed in the above background portion is provided only for better understanding of the background of the present disclosure, and thus it may contain information that does not form the prior art known by those ordinary skilled in the art.

### SUMMARY

The objective of the present disclosure is to provide a display panel and a manufacturing method thereof, and a display device.

In order to achieve the above-mentioned invention object, the present disclosure adopts the following technical solutions:

According to a first aspect of the present disclosure, there is provided a display panel, including:
a base substrate, including a display area and a non-display area;
a signal line layer, disposed on a side of the base substrate, the signal line layer including a plurality of signal lines, and the signal lines are at least partially located in the non-display area; and
a touch layer, disposed on a side of the signal line layer away from the base substrate, wherein the touch layer includes a plurality of touch lines, and the touch layer includes a first touch layer and a second touch layer arranged in a stacked manner, and a first insulating layer disposed between the first touch layer and the second touch layer, the touch lines are at least partially located in the non-display area, the plurality of touch lines include a plurality of first touch lines and a plurality of second touch lines arranged in a stacked manner, the first touch lines are disposed in the first touch layer, the second touch lines are disposed in the second touch layer, and each of the touch lines includes a first touch line and a second touch line connected in parallel;
wherein, the non-display area includes a first non-display area, the first non-display area is located at a periphery of the display area, and orthographic projections of the plurality of touch lines in the first non-display area on the base substrate at least partially overlap with orthographic projections of the plurality of signal lines on the base substrate;
in at least part of the touch lines within the first non-display area, the first touch line and the second touch line belonging to a same touch line respectively have a first center line and a second center line, and the first center line and the second center line are not aligned in a direction perpendicular to the extension of the touch line.

In an exemplary embodiment of the present disclosure, orthographic projections on the base substrate of at least part of the plurality of signal lines located in the non-display area are located within an orthographic projection on the base substrate of a combination of at least one of the first touch lines and at least one of the second touch lines.

In an exemplary embodiment of the present disclosure, orthographic projections of the first touch line and the second touch line belonging to the same touch line on the base substrate at least partially overlap, and the first touch line and the second touch line whose orthographic projections on the base substrate overlap are electrically connected through a via in the first insulating layer in one-to-one correspondence.

In an exemplary embodiment of the present disclosure, a width in a line width direction, of an overlapping area of an orthographic projection of the first touch line and an orthographic projection of the second touch line on the base substrate belonging to the same touch line, is not less than 1.5 μm.

In an exemplary embodiment of the present disclosure, the non-display area further includes a second straight area, and the second straight area is located at one side of the display area in the second direction; and
the first non-display area includes:
a first straight area, located at one side of the display area in the first direction; and
a first corner area, connecting the first straight area and the second straight area;
wherein, orthographic projections of the first touch lines on the base substrate and the orthographic projections of the second touch lines on the base substrate of at least part of the touch lines located in the first straight area or the first corner area are arranged alternately.

In an exemplary embodiment of the present disclosure, the first non-display area further includes:
a third straight area, disposed at a side of the display area away from the first straight area; and
a second corner area, connecting the second straight area and the third straight area;
wherein, the orthographic projections of the first touch lines on the base substrate and the orthographic projections of the second touch lines on the base substrate of at least part of the touch lines located in the third straight area or the second corner area are arranged alternately.

In an exemplary embodiment of the present disclosure, the first touch line and the second touch line each include a first straight segment, a first connecting segment, a first curved segment, a second connecting segment and a second straight segment connected in sequence, the first straight segment is located in the first straight area, the first connecting segment, the first curved segment and the second connecting segment are all located in the first corner area, and the second straight segment is located in the second straight area;
along a direction from the second straight area to the first corner area, an overlapping area of an orthographic projection of the second connecting segment of the first touch line on the base substrate and an orthographic projection of the corresponding second connecting segment of the second touch line on the base substrate gradually decreases.

In an exemplary embodiment of the present disclosure, the first touch line and the second touch line each further include a third connecting segment, a second curved segment, a fourth connecting segment and a third straight segment connected in sequence, the third connecting segment, the second curved segment and the fourth connecting segment are all located in the second corner area, and the third straight segment is located in the third straight area;
along a direction from the second straight area to the second corner area, an overlapping area of an orthographic projection of the third connecting segment of the first touch line on the base substrate and an orthographic projection of the corresponding third connecting segment of the second touch line on the base substrate gradually decreases.

In an exemplary embodiment of the present disclosure, a ratio of an overlapping area of an orthographic projection of the second straight segment of the first touch line on the base substrate and an orthographic projection of the second straight segment of the second touch line on the base substrate to an area of the second straight segment of the first touch line or an area of the second straight segment of the second touch line is not less than 95%.

In an exemplary embodiment of the present disclosure, the base substrate further includes an opening area, the opening area is located in the display area, and the non-display area further includes a second non-display area located between the opening area and the display area;
the touch layer further includes a plurality of touch electrodes, the plurality of touch electrodes include a plurality of first electrode groups extending along a first direction and a plurality of second electrode groups extending along a second direction, and the first electrode groups and the second electrode groups are insulated from each other;
at least one of the first electrode groups and at least one of the second electrode groups are divided by the opening area into two sub-electrode groups located on both sides of the opening area;
the touch line is connected to the two sub-electrode groups of the first electrode group or the touch line is connected to the two sub-electrode groups of the second electrode group;
wherein, orthographic projections of the plurality of touch lines in the second non-display area on the base substrate at least partially overlap with orthographic projections of the plurality of signal lines on the base substrate;
in at least part of the touch lines within the second non-display area, the first touch line and the second touch line belonging to a same touch line respectively have a first center line and a second center line, and the first center line and the second center line are not aligned in a direction perpendicular to the extension of the touch line.

In an exemplary embodiment of the present disclosure, orthographic projections of the first touch lines on the base substrate and orthographic projections of the second touch lines on the base substrate of at least part of the touch lines located in the second non-display area are arranged alternately.

In an exemplary embodiment of the present disclosure, a line width of the first touch line and the second touch line is not less than 4.2 μm; a spacing between two adjacent first touch lines is not less than 3 μm; and a spacing between two adjacent second touch lines is not less than 3 μm.

In an exemplary embodiment of the present disclosure, the signal line is a data signal line.

In an exemplary embodiment of the present disclosure, a display panel includes:
a base substrate, including a display area and a non-display area;
a signal line layer, disposed on a side of the base substrate, the signal line layer including a plurality of signal lines, and the signal lines are at least partially located in the non-display area; and
a touch layer, disposed on a side of the signal line layer away from the base substrate, the touch layer including a plurality of touch lines, and the touch lines are at least partially located in the non-display area;
the non-display area includes a first non-display area, the first non-display area is located at a periphery of the display area, and orthographic projections of the plurality of touch lines in the first non-display area on the base substrate at least partially overlap with orthographic projections of the plurality of signal lines on the base substrate;
in the first non-display area, the first gap is between orthographic projections of two adjacent touch lines on the base substrate, and the second gap is between orthographic projections of two adjacent touch lines in the non-display area other than the first non-display area on the base substrate, and the first gap is smaller than the second gap.

In an exemplary embodiment of the present disclosure, the touch layer includes a first touch layer and a second touch layer arranged in a stacked manner, and a first insulating layer disposed between the first touch layer and the second touch layer, each of the plurality of touch lines includes a first touch line and a second touch line connected in parallel, the first touch line is disposed in the first touch layer, and the second touch line is disposed in the second touch layer; and among at least some of the touch lines, orthographic projections of the first touch line and the second touch line belonging to the same touch line on the base substrate at least partially overlap,
a unit overlapping area between the first touch line and the second touch line in the first non-display area is smaller than a unit overlapping area between the first touch line and the second touch line of the second straight area in a non-display area other than the first non-display area.

In an exemplary embodiment of the present disclosure, the first touch line includes a first side and a second side that are oppositely disposed, and the second touch line includes a third side and a fourth side that are oppositely disposed;
in the first non-display area, an orthographic projection of the third side on the base substrate is located between orthographic projections of the first side and the second side on the base substrate, and the orthographic projection of the second side on the base substrate is located between orthographic projections of the third side and the fourth side on the base substrate.

In an exemplary embodiment of the present disclosure, in the first non-display area, a minimum distance between the orthographic projections of a first side and a fourth side of two adjacent touch lines on the base substrate is the first gap; and
in the non-display area except the first non-display area, the minimum distance between the orthographic projections of the first side and the fourth side of two adjacent touch lines on the base substrate is the second gap.

In an exemplary embodiment of the present disclosure, the first gap is 0.1 to 0.3 times the second gap.

According to a second aspect of the present disclosure, a method for manufacturing display panel is provided, including:
providing a base substrate, the base substrate including a display area and a non-display area;
forming a signal line layer on a side of the base substrate, wherein the signal line layer includes a plurality of signal lines, and at least part of the signal lines are located in the non-display area; and
forming a touch layer on a side of the signal line layer away from the base substrate, wherein the touch layer includes a plurality of touch lines, and the touch layer includes a first touch layer and a second touch layer arranged in a stacked manner, and a first insulating layer disposed between the first touch layer and the second touch layer, the touch lines are at least partially located in the non-display area, the plurality of touch lines include a plurality of first touch lines and a plurality of second touch lines arranged in a stacked manner, the first touch lines are disposed in the first touch layer, the second touch lines are disposed in the second touch layer, and each of the touch lines includes a first touch line and a second touch line connected in parallel;
wherein, the non-display area includes a first non-display area, the first non-display area is located at a periphery of the display area, and orthographic projections of the plurality of touch lines in the first non-display area on the base substrate at least partially overlap with orthographic projections of the plurality of signal lines on the base substrate;
in at least part of the touch lines within the first non-display area, the first touch line and the second touch line belonging to a same touch line respectively have a first center line and a second center line, and the first center line and the second center line are not aligned in a direction perpendicular to the extension of the touch line.

In an exemplary embodiment of the present disclosure, a material of the touch layer includes titanium and aluminum, and the formation temperature of the touch layer does not exceed 85° C.

According to a third aspect of the present disclosure, a display device is provided, including a display panel according to the first aspect.

It is to be understood that both the foregoing general description and the following detailed description are exemplary and explanatory only and are not restrictive of the present disclosure.

### BRIEF DESCRIPTION OF THE DRAWINGS

The above and other features and advantages of the present disclosure will become more apparent by describing in detail example embodiments thereof with reference to the attached drawings.

FIG. 1 is a schematic diagram of a planar structure of a base substrate in an exemplary embodiment of the present disclosure;

FIG. 2 is a schematic cross-sectional view of a non-display area of a display panel in an exemplary embodiment of the present disclosure;

FIG. 3 is a schematic diagram of the distribution position of signal lines in an exemplary embodiment of the present disclosure;

FIG. 4 is a schematic cross-sectional view of a display area of a display panel in an exemplary embodiment of the present disclosure;

FIG. 5 is a schematic diagram of the distribution positions of the signal line layer and the touch layer in an exemplary embodiment of the present disclosure;

FIG. 6 is a schematic diagram of the signal line arrangement in the area A of FIG. 5;

FIG. 7 is a schematic diagram of the arrangement of the first touch line and the second touch line in the area A in FIG. 5;

FIG. 8 is a schematic diagram of a stack of signal lines, first touch lines, and second touch lines in the area A of FIG. 5;

FIG. 9 is a schematic diagram of the signal line arrangement in the area B of FIG. 5;

FIG. 10 is a schematic diagram of the arrangement of the first touch line and the second touch line in the area B of FIG. 5;

FIG. 11 is a schematic diagram of a stack of signal lines, first touch lines, and second touch lines in the area B of FIG. 5;

FIG. 12 is a schematic diagram of the signal line arrangement in the area C of FIG. 5;

FIG. 13 is a schematic diagram of the arrangement of the first touch line and the second touch line in the area C in FIG. 5;

FIG. 14 is a schematic diagram of a stack of signal lines, first touch lines, and second touch lines in the area C in FIG. 5;

FIG. 15 is a schematic diagram of the arrangement of the first touch line and the second touch line in the area D in FIG. 5;

FIG. 16 is a schematic diagram of the arrangement of the first touch line and the second touch line in the area E in FIG. 5;

FIG. 17 is a schematic diagram of the arrangement of the first touch line and the second touch line in the area F in FIG. 5;

FIG. 18 is a schematic diagram of the arrangement of the first touch line and the second touch line in the area G in FIG. 5;

FIG. 19 is a schematic diagram of the arrangement of the first touch line and the second touch line in the area H in FIG. 5;

FIG. 20 is a schematic diagram of the arrangement of the first touch line and the second touch line layer in the area I in FIG. 5;

FIG. 21 is a schematic diagram of the arrangement of touch lines in the second non-display area in an exemplary embodiment of the present disclosure;

FIG. 22 is a schematic diagram of the arrangement of touch lines in the second non-display area in another exemplary embodiment of the present disclosure;

FIG. 23 is a schematic diagram of the arrangement of the first touch line and the second touch line in the area J in FIG. 22;

FIG. 24 is a schematic diagram of the arrangement of the first touch line and the second touch line in the area K in FIG. 22;

FIG. 25 is a structural schematic diagram of a first center line of a first touch line in an exemplary embodiment of the present disclosure;

FIG. 26 is a structural schematic diagram of a second center line of a second touch line in an exemplary embodiment of the present disclosure;

FIG. 27 is a cross-sectional view in the direction of A-A′ in FIG. 7;

FIG. 28 is a schematic diagram of the structure of the first gap and the second gap in an exemplary embodiment of the present disclosure.

The main components in the figure are described as follows:
Y—first direction; X—second direction; 100—base substrate; 110—display area; 120—non-display area; 121—first straight area; 122—second straight area; 123—third straight area; 124—first corner area; 125—second corner area; 126—second non-display area; 127—binding area; 130—opening area; 200—signal line layer; 210—signal line; 213—data signal line; 214—scanning signal line; 215—light shielding layer; 216—active layer; 217—first gate insulating layer; 218—first gate metal layer; 219—second gate insulating layer; 220—second gate metal layer; 221—interlayer dielectric layer; 222—first source-drain layer; 223—first planarization layer; 224—second source-drain layer; 225—second planarization layer; 226—first electrode layer; 227—light emitting functional layer; 228—second electrode layer; 229—pixel definition layer; 230—encapsulation layer; 300—touch layer; 301—first touch layer; 302—second touch layer; 303—first insulating layer; 304—second insulating layer; 305—protective layer; 310—touch line; 311—first touch line; 312—second touch line; 313—first straight segment; 314—first connecting segment; 315—first curved segment; 316—second connecting segment; 317—second straight segment; 318—third connecting segment; 319—second curved segment; 320—fourth connecting segment; 321—third straight segment; 330—first electrode group; 331—second electrode group; 332—first electrode; 333—second electrode; 334—first bridge line; 335—second bridge line; 336—first connection line; 337—second connection line; 400—chip; O1—first center line; O2—second center line; L1—first gap; L2—second gap.

### DETAILED DESCRIPTION

Example embodiments will now be described more fully with reference to the accompanying drawings. However, example embodiments can be implemented in a variety of forms and should not be construed as limited to the embodiments set forth herein; rather, these embodiments are provided so that the present disclosure will be comprehensive and complete and fully convey the concepts of the example embodiments to those skilled in the art. The same reference numerals in the figures represent the same or similar structures, and thus their detailed descriptions will be omitted. In addition, the drawings are only schematic illustrations of the present disclosure and are not necessarily drawn to scale.

Although relative terms such as “upper” and “lower” are used in this specification to describe the relative relationship of one component of the illustration to another component, these terms are used in this specification only for convenience, such as according to the orientation of the examples described in the drawings. It is understood that if the device of the illustration is turned upside down, the component described as “upper” will become the component “lower”. When a structure is “on” other structures, it may mean that the structure is formed integrally on the other structure, or that the structure is “directly” disposed on the other structure, or that the structure is “indirectly” disposed on the other structure through another structure.

The terms “a”, “an”, “the”, “said” and “at least one” are used to indicate the presence of one or more elements/components/etc.; the terms “including” and “having” are used to express an open-ended inclusive meaning and mean that additional elements/components/etc. may exist in addition to the listed elements/components/etc.; the terms “first”, “second” and “third” etc. are used merely as labels and are not intended to limit the quantity of their objects.

A transistor is an element including at least three terminals: a gate electrode, a drain electrode, and a source electrode. A transistor has a channel region between a drain electrode (drain electrode terminal, drain region, or drain electrode) and a source electrode (source electrode terminal, source region, or source electrode), and current can flow through the drain electrode, the channel region, and the source electrode. The channel region refers to the region where current mainly flows.

The first electrode may be a drain electrode and the second electrode may be a source electrode, or the first electrode may be a source electrode and the second electrode may be a drain electrode. In the case of using transistors with opposite polarities or when the current direction changes during circuit operation, the functions of the “source electrode” and the “drain electrode” are sometimes interchanged. Therefore, in this specification, the “source electrode” and the “drain electrode” may be interchanged.

In the related art, the display panel includes abase substrate and a plurality of sub-pixels and a plurality of signal lines arranged on a side of the base substrate. The signal lines are used to connect the sub-pixels and peripheral chips, etc., to control the operating state of each sub-pixel. The display panel includes a display area and a peripheral area. The signal lines are usually densely arranged in the peripheral area. The signal lines are made of metal materials. When strong light is irradiated to the display panel, the densely arranged signal lines in the periphery are easy to reflect the light, thereby affecting the display quality.

As shown in FIGS. 1, 2, 5, 7, 25 and 26, a display panel is provided in an embodiment of the present disclosure, including a base substrate 100, a signal line layer 200 and a touch layer 300, wherein the base substrate 100 includes a display area 110 and a non-display area 120; the signal line layer 200 is disposed on a side of the base substrate 100, the signal line layer 200 includes a plurality of signal lines 210, and the signal lines 210 are at least partially located in the non-display area 120; the touch layer 300 is disposed on a side of the signal line layer 200 away from the base substrate 100, the touch layer 300 includes a plurality of touch lines 310, and the touch layer 300 includes a first touch layer 301 and a second touch layer 302 which are stacked, and a first insulating layer 303 disposed between the first touch layer 301 and the second touch layer 302, and the touch lines 310 are at least partially located in the non-display area 120, the multiple touch lines 310 include multiple first touch lines 311 and multiple second touch lines 312 that are stacked, the first touch lines 311 are disposed in the first touch layer 301, the second touch lines 312 are disposed in the second touch layer 302, and each touch line 310 includes a first touch line 311 and a second touch line 312 connected in parallel; wherein the non-display area 120 includes a first non-display area, and the first non-display area is located outside the display area 110, and the orthographic projections of the multiple touch lines 310 in the first non-display area on the base substrate 100 at least partially overlap with the orthographic projections of the multiple signal lines 210 on the base substrate 100. In at least part of the touch lines 310 in the first non-display area, the first touch line 311 and the second touch line 312 belonging to the same touch line 310 respectively have a first center line O1 and a second center line O2, and in a direction perpendicular to the extension of the touch line 310, the first center line O1 and the second center line O2 are not aligned.

In the display panel provided by the present disclosure, in at least part of the touch lines 310 in the first non-display area, the first touch line 311 and the second touch line 312 belonging to the same touch line 310 respectively have a first center line O1 and a second center line O2, and in a direction perpendicular to the extension of the touch line 310, the first center line and the second center line are staggered. In this way, the area of the first touch line 311 and the second touch line 312 used to block the signal line 210 is increased, which can reduce the reflection of light by the signal line 210 in the area, and avoid the area from reflecting and shining under strong light and affecting the display quality.

The components of the display panel provided in the embodiment of the present disclosure are described in detail below with reference to the accompanying drawings.

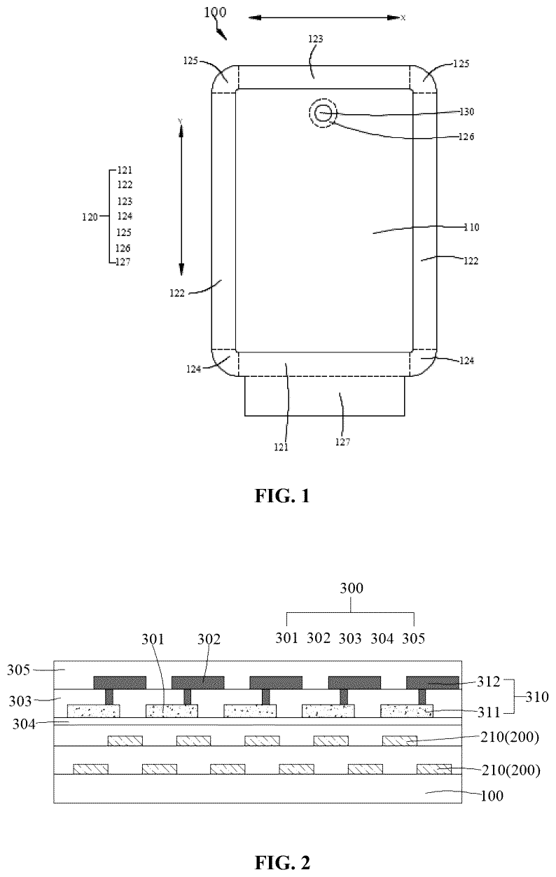

As shown in FIG. 1 and FIG. 2, the present disclosure provides a display panel, which may be an OLED (Organic Light-Emitting Diode) display panel. The display panel includes a base substrate 100, a signal line layer 200 and a touch layer 300.

The base substrate 100 includes a display area 110 and a non-display area 120. The display area 110 is used to display an image. The non-display area 120 can be located at multiple positions of the display area 110, and the non-display area 120 can include multiple areas. In some embodiments of the present disclosure, the non-display area 120 includes a first non-display area, which is located at the periphery of the display area 110. The non-display area 120 also includes a second straight area 122, which is located at least on one side of the display area 110 in the second direction X. The first non-display area includes a first straight area 121 and a first corner area 124. In the embodiment, the first straight area 121 is located on one side of the display area 110 in the first direction Y; the first corner area 124 connects the first straight area 121 and the second straight area 122. The non-display area 120 also includes a binding area 17, and the binding area 127 is located on the side of the first straight area 121 away from the display area 110. The number of the second straight areas 122 can be one or two. Specifically in one embodiment, the number of the second straight areas 122 is two, which are located on both sides of the display region 110 in the second direction X, and the number of the first corner areas 124 is two, which are connected between the first straight area 121 and the second straight areas 122. Further, the first non-display region further includes a third straight area 123 and a second corner area 125, the third straight area 123 is located on a side of the display region 110 away from the first straight area 121; the second corner area 125 connects the second straight area 122 and the third straight area 123. The number of the second corner areas 125 may be two.

In some embodiments of the present disclosure, the base substrate 100 further includes an opening area 130, which is located in the display area 110. The opening area 130 can be used to dispose functional modules such as a camera, a distance sensor, a flash or a speaker. The shape of the opening area 130 can be an ellipse, a circle, a square or a rounded rectangle. In this embodiment, the non-display area includes a second non-display area 126 located between the opening area 130 and the display area 110. The second non-display area 126 can be an annular area surrounding the opening area 130. The non-display area 120 includes the second non-display area 126. Of course, in some embodiments, the first non-display area may include the above-mentioned first straight area 121, the first corner area 124, the third straight edge area, the second corner area 125 and the second non-display area 126.

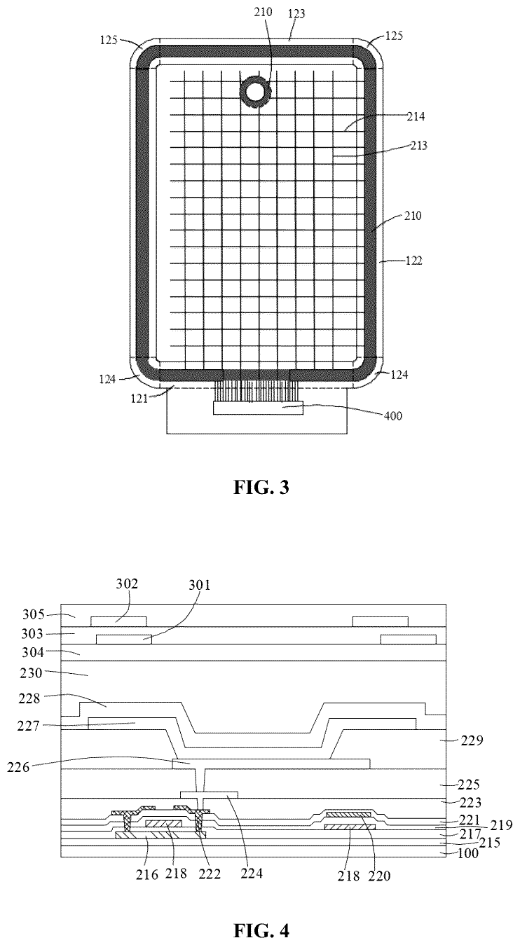

As shown in FIGS. 1 to 3, the signal line layer 200 is disposed on a side of the base substrate 100. The signal line layer 200 includes a plurality of signal lines 210, and the signal lines 210 can be used to transmit a variety of signals. The display panel also includes a plurality of sub-pixels, and the signal lines 210 can be connected to the sub-pixels and the peripheral chip 400 to transmit a variety of signals for the sub-pixels. For example, the signal lines 210 include scanning signal lines 214 for transmitting scanning signals, data signal lines 213 for transmitting data signals, and light-emission signal lines for transmitting light-emission signals, etc., which are not specifically limited in the present disclosure. The signal lines 210 can be located in the display area 110 and the non-display area 120, and different signal lines 210 are distributed at different positions on the base substrate 100. In the present disclosure, the signal lines 210 are at least partially located in the non-display area 120. That is, the signal lines 210 can be divided into a plurality of segments, some of which can be located in the display area 110, and some of which can be located in the non-display area 120. For example, some segments of the data signal line 213 are located in the display area 110, and some segments are located in the non-display area 120, such as the first straight area 121 or the first corner area 124 or the second non-display area 126. For another example, some segments of the scan signal line 214 are located in the display area 110, and some segments are located in the second straight area 122 or the first corner area 124 or the second non-display area 126. For another example, some segments of the light-emission signal line are located in the display area 110, and some segments are located in the second non-display area 126. Further, in the present disclosure, the signal line 210 may be the data signal line 213.

In the present disclosure, the signal line layer 200 may include multiple metal layers, different signal lines 210 may be disposed in different metal layers, and different segments of the same signal line 210 may also be disposed in different metal layers, which is not specifically limited in the present disclosure. The material of the signal line 210 may be a metal material, such as molybdenum (Mo) or copper (Cu), etc., but is not limited thereto. In some embodiments of the present disclosure, the number of signal lines 210 located in the first corner area 124, the first straight area 121, and the second non-display area 126 is large, and the arrangement is relatively dense. For example, the spacing between two adjacent signal lines 210 located in the first corner area 124 or the first straight area 121 does not exceed 1.5 μm, which is for example 1 μm, 0.5 μm or 0.1 μm, etc.

As shown in FIG. 4, in some embodiments of the present disclosure, the display panel further includes a driving circuit layer and a light-emitting device layer, and the driving circuit layer may include the above-mentioned signal line layer 200. The driving circuit layer may be formed in a multilayer film structure. The light-emitting device layer includes a plurality of light-emitting devices. The driving circuit layer may include a pixel circuit, and the pixel circuit is used to drive the light-emitting device of the OLED display panel to emit light. Each sub-pixel may include a pixel circuit and a light-emitting device. The pixel circuit may be a pixel circuit such as 7T1C, 7T2C, 6T1C or 6T2C, and its structure is not specifically limited here. In the embodiment, nTmC means that a pixel circuit includes n transistors (represented by the letter “T”) and m capacitors (represented by the letter “C”). The number of pixel circuits is multiple, and one pixel circuit correspondingly drives one light-emitting device to emit light. The data signal line 213 is connected to the source or drain of the transistor in the pixel circuit.

Taking the transistor in the driving circuit as a top-gate thin film transistor as an example, the driving circuit layer includes an active layer 216, a first gate insulation layer 217, a first gate metal layer 218, a second gate insulation layer 219, an interlayer dielectric layer 221, a first source-drain layer 222, a first planarization layer 223, a second source-drain layer 224 and a second planarization layer 225.

The active layer 216 is disposed on a side of the base substrate 100; the first gate insulating layer 217 is disposed on the side of the active layer 216 away from the base substrate 100, and the first gate insulating layer 217 covers the active layer 216; the first gate metal layer 218 is disposed on the side of the first gate insulating layer 217 away from the base substrate 100, and the first gate metal layer 218 may include the gate of the transistor and the first electrode plate of the capacitor. The second gate insulating layer 219 is disposed on the side of the first gate metal layer 218 away from the base substrate 100, and the second gate insulating layer 219 covers the first gate metal layer 218; the second gate metal layer 220 is disposed on the side of the second gate insulating layer 219 away from the base substrate 100, and the second gate metal layer 220 may include a second electrode plate of a capacitor, and the interlayer dielectric layer 221 is disposed on the side of the second gate insulating layer 219 away from the base substrate 100; the first source-drain layer 222 is disposed on the side of the interlayer dielectric layer 221 away from the base substrate 100, and the first source-drain layer 222 includes a source and a drain of a transistor, and the source and the drain are connected to the active layer 216. The first planarization layer 223 is disposed on the side of the first source-drain layer 222 away from the base substrate 100, the second source-drain layer 224 is disposed on the side of the first planarization layer 223 away from the base substrate 100, and the second planarization layer 225 is disposed on the side of the second source-drain layer 224 away from the base substrate 100. Furthermore, the driving circuit layer further includes a light shielding layer 215 disposed between the base substrate 100 and the active layer 216.

The signal line layer 200 may include a first gate metal layer 218, a second gate metal layer 220, a first source-drain layer 222, and a second source-drain layer 224. The signal line 210 may be distributed in any layer of these conductive layers. It should be noted that the structure of the driving circuit layer of the display panel may also be other structures, such as a driving circuit layer including a bottom-gate transistor, which is not specifically limited in the present disclosure.

The light emitting device layer is disposed on a side of the driving circuit layer away from the base substrate 100. The light emitting device layer further includes a pixel definition layer 229, and the pixel definition layer 229 separates a plurality of light emitting devices.

The pixel definition layer 229 is disposed on the side of the driving circuit layer away from the base substrate 100. The pixel definition layer 229 includes a plurality of pixel openings, and the range defined by each pixel opening is the range of a light-emitting device. The shape of the pixel opening, that is, the shape of the profile of the orthographic projection of the pixel opening on the base substrate 100, can be a polygon, a smooth closed curve or other shapes, which are not specifically limited here.

Taking the light-emitting device being an OLED light-emitting device as an example, the light-emitting device includes a first electrode layer 226, a light-emitting functional layer 227, and a second electrode layer 228 arranged in sequence in a direction away from the base substrate 100. The first electrode layer 226 can be used as an anode layer of the light-emitting device. The light-emitting functional layer 227 covers the first electrode layer 226, and the second electrode layer 228 covers the light-emitting functional layer 227. The first electrode layer 226 can be connected to the source/drain of the transistor. The second electrode layer 228 can cover the light-emitting functional layer 227, which can be used as a cathode layer of the light-emitting device. The second electrode layer 228 can be a single layer or a multilayer structure, and its material can include one or more of conductive metals, metal oxides, and alloys. The light-emitting functional layer 227 is at least partially disposed in the pixel opening, and can include a hole injection layer, a hole transport layer, a light-emitting material layer, an electron transport layer, and an electron injection layer stacked in sequence in a direction away from the base substrate 100. The holes and electrons can be compounded into excitons in the light-emitting material layer, and the excitons radiate photons, thereby generating visible light. The specific light-emitting principle is not described in detail here.

In some embodiments, the signal line layer 200 may also include a first electrode layer 226 and a second electrode layer 228, that is, the signal line 210 may be distributed in the first electrode layer 226 and the second electrode layer 228.

The display panel also includes an encapsulation layer 230, which is arranged on the side of the light-emitting device layer away from the base substrate 100, and can be used to protect the light-emitting device layer and prevent external water and oxygen from corroding the light-emitting device. In some embodiments of the present disclosure, encapsulation can be achieved by thin-film encapsulation (TFE). Specifically, the encapsulation layer 230 may include a first inorganic layer, an organic layer, and a second inorganic layer, wherein the first inorganic layer covers the surface of the light-emitting device layer away from the base substrate 100, the organic layer may be disposed on the surface of the first inorganic layer away from the base substrate 100, and the boundary of the organic layer is limited to the inner side of the boundary of the first inorganic layer, and the second inorganic layer covers the organic layer and the first inorganic layer not covered by the organic layer, and the second inorganic layer can be used to block the intrusion of water and oxygen, and the flexible organic layer can be used to achieve flattening.

As shown in FIGS. 1, 2, 4 and 5, the touch layer 300 is disposed on a side of the signal line layer 200 away from the base substrate 100. Specifically, the touch layer 300 is disposed on a side of the encapsulation layer 230 away from the base substrate 100. The touch layer 300 includes a plurality of touch electrodes and a plurality of touch lines 310. The touch electrodes are located in the display area 110. The touch lines 310 may be located in different areas of the base substrate 100. In some embodiments, the touch lines 310 are located at the periphery of the display area 110, that is, the touch lines 310 are located in the first straight area 121, the second straight area 122 or the first corner area 124. Such touch lines 310 may connect the touch electrodes to the integrated circuit or the flexible circuit board. In other embodiments, the touch lines 310 may be located in the second non-display area 126, and are used to connect the touch electrodes on both sides of the second non-display area 126. The plurality of touch lines 310 are arranged in different layers. That is, among the multiple touch lines 310, some touch lines 310 may be located in the same layer, and some touch lines 310 may be distributed in another layer. Of course, the touch lines 310 transmitting the same signal may also be distributed in different layers, which is not specifically limited in the present disclosure.

In some embodiments of the present disclosure, the plurality of touch electrodes include a plurality of first electrode groups 330 extending along a first direction Y and a plurality of second electrode groups 331 extending along a second direction X. The plurality of first electrode groups 330 may be arranged in sequence along the second direction X, and the plurality of second electrode groups 331 may be arranged in sequence along the first direction Y The first electrode group 330 and the second electrode group 331 are insulated from each other. The first direction Y and the second direction X are substantially perpendicular. The first electrode group 330 may be a driving electrode group connected to a driving circuit, and the second electrode group 331 may be a detection electrode group connected to a detection circuit. Alternatively, the first electrode group 330 is a detection electrode group connected to a detection circuit, and the second electrode group 331 is a driving electrode group connected to a driving circuit. Specifically, the first electrode group 330 and the second electrode group 331 may be connected to the corresponding driving circuit or detection circuit through the touch line 310 located at the periphery of the display area 110. When a user's finger touches the touchable area of the display panel, the mutual capacitance of the first electrode group 330 and the second electrode group 331, which are insulated and cross-arranged at the touch point, changes. The driving circuit scans the driving electrode groups in the first electrode group 330 and the second electrode group 331 one by one, and reads the signals of the detection electrode groups in the first electrode group 330 and the second electrode group 331 each time a driving electrode group is scanned. After one round of scanning, the coordinates of the touch point can be determined, and the content corresponding to the touch operation is responded to based on the coordinates of the touch point.

In some embodiments, the plurality of touch lines 310 may include a plurality of first touch lines 311 and a plurality of second touch lines 312. The touch layer 300 includes a first touch layer 301 and a second touch layer 302 which are stacked. The second touch layer 302 is disposed on a side of the first touch layer 301 away from the base substrate 100. Further, the touch layer 300 may also include a first insulating layer 303 disposed between the first touch layer 301 and the second touch layer 302. The first touch lines 311 may be distributed in the first touch layer 301, and the second touch lines 312 may be distributed in the second touch layer 302. Each touch line 310 includes a first touch line 311 and a second touch line 312 which are connected in parallel. In the first non-display area, the orthographic projections of the plurality of touch lines 310 on the base substrate 100 at least partially overlap with the orthographic projections of the plurality of signal lines 210 on the base substrate 100. In at least part of the touch lines 310 in the first non-display area, the first touch line 311 and the second touch line 312 belonging to the same touch line 310 respectively have a first center line O1 and a second center line O2, and in a direction perpendicular to the extension of the touch line 310, the first center line O1 and the second center line O2 are staggered, so that the covering area of the touch line 310 on the signal line 210 is increased while the resistance of the touch line 310 is reduced.

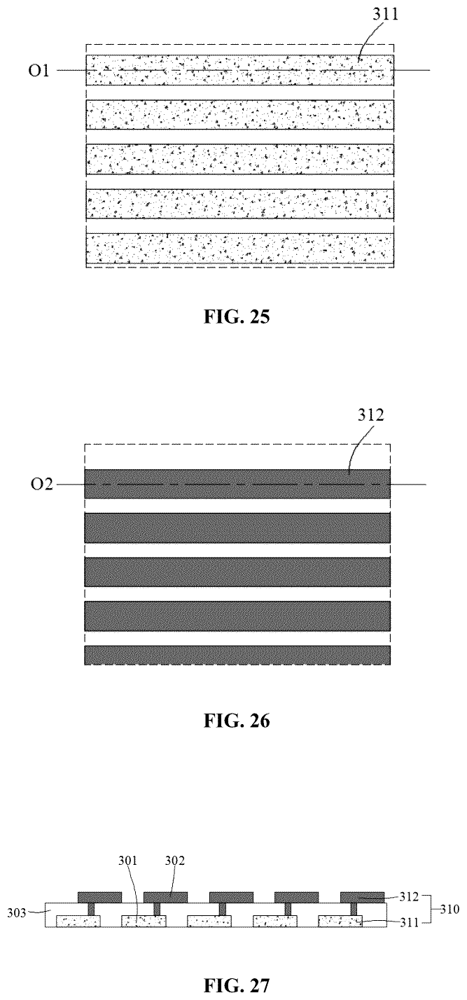

As shown in FIG. 25 and FIG. 26, in the present disclosure, the first center line O1 refers to a line connecting center points of the line width of the first touch line 311, and the second center line O2 refers to a line connecting center points of the line width of the second touch line 312.

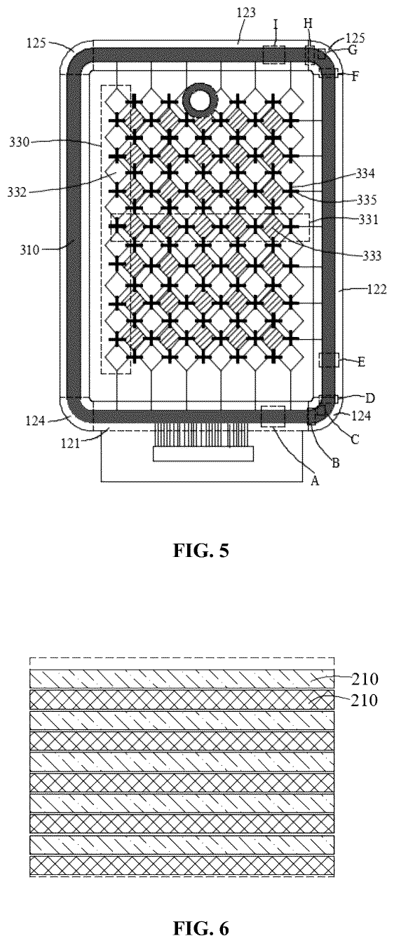

As shown in FIG. 1, FIG. 2 and FIG. 5, FIG. 2 is a cross-sectional schematic diagram of a non-display area 120 of a display panel in an embodiment. In the present disclosure, the light reflection capability of the touch layer 300 is lower than that of the signal line layer 200. The first center line O1 and the second center line O2 are staggered, and compared with the first center line O1 and the second center line O2 being aligned to each other, the arrangement of the present disclosure helps to increase the covering area of the touch line 310 to the signal line 210. In this way, the reflection of light by the signal line 210 in the area can be reduced, which prevents the area from being luminous under strong light and affecting the display quality. In some embodiments of the present disclosure, the material of the touch layer 300 can be formed as a conductive layer containing titanium (Ti) and aluminum (Al) by a low temperature process. Further, the orthographic projection on the base substrate 100 of at least part of the plurality of signal lines 210 located in the non-display area 120 is located within the orthographic projection on the base substrate 100 of the combination of at least one first touch line 311 and at least one second touch line 312.

The touch lines 310 may be located in different areas of the base substrate 100, and the touch lines 310 in different areas may be arranged in different manners. The touch layer 300 may further include a second insulating layer 304 and a protective layer 305, wherein the second insulating layer 304 is arranged between the signal line layer 200 and the first touch layer 301, and the protective layer 305 is arranged on a side of the second touch layer 302 away from the base substrate 100.

Hereinafter, the covering of the signal line 210 by the touch line 310 will be described in detail in combination with the touch lines 310 at different positions.

As shown in FIG. 1, FIG. 2 and FIG. 5, in some embodiments of the present disclosure, the touch line 310 is located at the periphery of the display area 110, such as the first straight area 121, the second straight area 122 and the first corner area 124. It should be noted here that “at least part of the plurality of signal lines 210 located in the non-display area 120” refers to at least part of the signal lines 210 among all the plurality of signal lines 210 located in the non-display area 120, such as the signal line 210 located in the first straight area 121 or the signal line 210 located in the first corner area 124. For example, the first touch line 311 and the second touch line 312 belonging to the same touch line 310 located in the first straight area 121 or the first corner area 124 respectively have a first center line O1 and a second center line O2, and in the direction perpendicular to the extension of the touch line 310, the first center line O1 and the second center line O2 are staggered, as shown in FIG. 5 to FIG. 15.

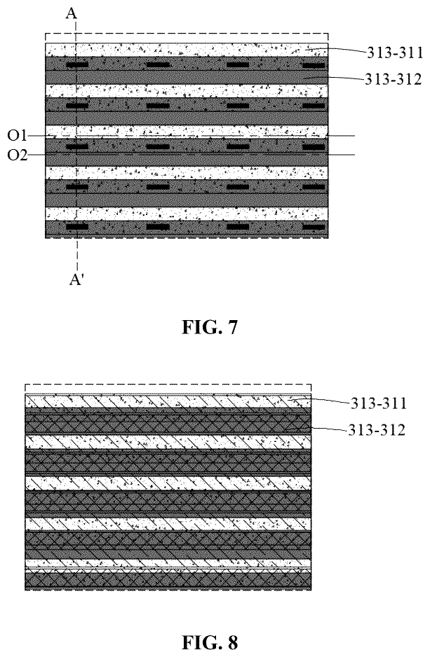

In the embodiment, FIG. 6 is an arrangement diagram of the signal line 210 in the area A in FIG. 5, that is, an arrangement diagram of the signal line 210 in the first straight area 121. In the figure, the signal line 210 is distributed in different metal layers. Different filling patterns in the figure represent different metal layers, and the same filling pattern represents the same metal layer. FIG. 7 is an arrangement diagram of the first touch line 311 and the second touch line 312 in the area A in FIG. 5, that is, an arrangement diagram of the first touch line 311 and the second touch line 312 in the first straight area 121. FIG. 8 is a stacking diagram of the signal line 210, the first touch line 311 and the second touch line 312 in the area A in FIG. 5, that is, a diagram of the layers of the signal line 210, the first touch line 311 and the second touch line 312 in the first straight area 121.

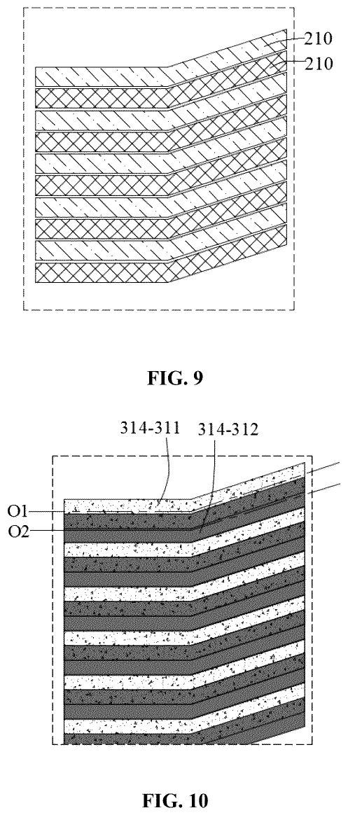

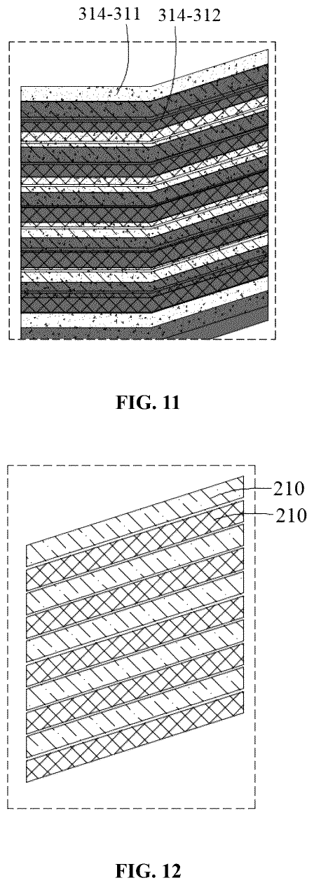

FIG. 9 is a layout diagram of the signal line 210 in the area B in FIG. 5, that is, the layout diagram of the signal line 210 at the connection of the first straight area 121 and the first corner area 124. In the figure, the signal line 210 is distributed in different metal layers. Different filling patterns in the figure represent different metal layers, and the same filling pattern represents the same metal layer. FIG. 10 is a layout diagram of the first touch line 311 and the second touch line 312 in the area B in FIG. 5, that is, the layout diagram of the first touch line 311 and the second touch line 312 at the connection of the first straight area 121 and the first corner area 124. FIG. 11 is a stacking diagram of the signal line 210, the first touch line 311 and the second touch line 312 in the area B in FIG. 5, that is, the layer diagram of the signal line 210, the first touch line 311 and the second touch line 312 at the connection of the first straight area 121 and the first corner area 124.

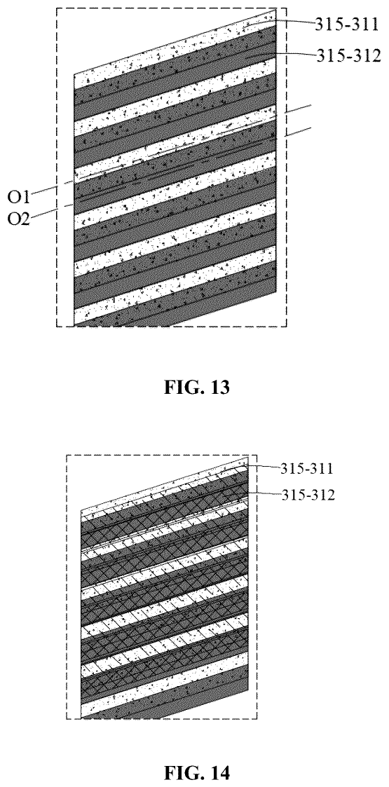

FIG. 12 is a layout diagram of the signal line 210 in the area C of FIG. 5, that is, a layout diagram of the signal line 210 in the first corner area 124. In the figure, the signal line 210 is distributed in different metal layers. Different filling patterns in the figure represent different metal layers, and the same filling pattern represents the same metal layer. FIG. 13 is a layout diagram of the first touch line 311 and the second touch line 312 in the area C of FIG. 5, that is, a layout diagram of the first touch line 311 and the second touch line 312 in the first corner area 124. FIG. 14 is a stacking diagram of the signal line 210, the first touch line 311 and the second touch line 312 in the area C of FIG. 5, that is, a diagram of the layers of the signal line 210, the first touch line 311 and the second touch line 312 in the first corner area 124.

FIG. 15 is a layout diagram of the first touch line 311 and the second touch line 312 in the area D in FIG. 5, that is, a layout diagram of the first touch line 311 and the second touch line 312 at the connection between the first corner area 124 and the second straight area 122. The dotted line in FIG. 15 is the boundary between the first corner area 124 and the second straight area 122. Since the present disclosure does not specifically limit the arrangement of the signal line 210, the arrangement diagram of the signal line 210 in the area D in FIG. 5 is not shown, and the specific arrangement diagram of the signal line 210 in other areas, such as the arrangement diagram of the signal line 210 in the area A, can be referred to.

It can be seen from FIGS. 5 to 15 that the first touch line 311 and the second touch line 312 belonging to the same touch line 310 located in the first straight area 121 or the first corner area 124 have a first center line O1 and a second center line O2 respectively. In the direction perpendicular to the extension of the touch line 310, the first center line O1 and the second center line O2 are staggered, and the combination of the first touch line 311 and the second touch line 312 covers most of the signal line 210 located in the area.

The first touch line 311 and the second touch line 312 belonging to the same touch line 310 located in the second straight area 122 have corresponding first center line O1 and second center line O2. In the direction perpendicular to the extension of the touch line 310, the first center line O1 and the second center line O2 can be staggered or not. That is, the combination of the first touch line 311 and the second touch line 312 located in the second straight area 122 can cover a large area or cover less of the signal line 210 located in the area relative to the first straight area 121 and the first corner area 124.

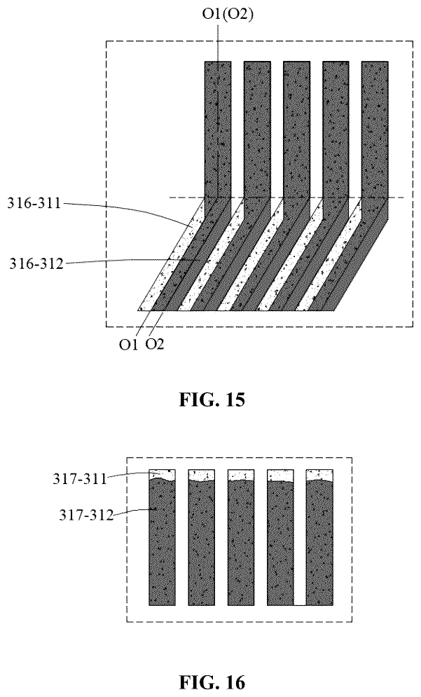

In practical applications, the number of signal lines 210 in the second straight area 122 is usually less than the number of signal lines 210 in the first straight area 121 and the first corner area 124. Therefore, even if the signal lines 210 in the second straight area 122 are not covered in a large area, the area is less likely to shine under strong light. As shown in FIGS. 5 and 16, FIG. 16 is an arrangement diagram of the first touch line 311 and the second touch line 312 in the area E in FIG. 5. In this figure, the first touch line 311 and the second touch line 312 are basically overlapped, and there is a gap between adjacent touch lines 310. In FIG. 16, the second touch line 312 is truncated for ease of illustration. Of course, preferably, the first touch line 311 and the second touch line 312 belonging to the same touch line 310 located in the second straight area 122 have a first center line O1 and a second center line O2, respectively, and in the direction perpendicular to the extension of the touch line 310, the first center line O1 and the second center line O2 are staggered. In this embodiment, the arrangement of the first touch line 211 and the second touch line 212 may refer to the first straight area 121.

Further, other areas outside the display area 110 may also be similar to this. For example, the first touch line 311 and the second touch line 312 belonging to the same touch line 310 located in the third straight area 123 or the second corner area 125 have a first center line O1 and a second center line O2 respectively, and in the direction perpendicular to the extension of the touch line 310, the first center line O1 and the second center line O2 are staggered. In the embodiment, the arrangement of the first touch line 211 and the second touch line 212 in the third straight area 123 can refer to the first straight area 121, and the arrangement of the first touch line 121 and the second touch line 122 in the second corner area 125 can refer to the first corner area 124. For example, as shown in FIG. 18, FIG. 18 is a schematic diagram of the arrangement of the first touch line 311 and the second touch line 312 in the area G in FIG. 5, which is similar to the arrangement of the first corner area 124.

As shown in FIG. 7, FIG. 10 and FIG. 13, further, in the first straight area 121 or the first corner area 124, the orthographic projection of the first touch line 311 on the base substrate 100 and the orthographic projection of the second touch line 312 on the base substrate 100 are arranged alternately. That is, in the first straight area 121 and the first corner area 124, the arrangement of the first touch line 311 and the second touch line 312 is: first touch line 311, second touch line 312, first touch line 311, second touch line 312 . . . , and so on. The spacing between two adjacent first touch lines 311 is not less than 3 μm, and the spacing between two adjacent second touch lines 312 is not less than 3 μm, so as to avoid mutual interference of signal transmission. Of course, in the third straight area 123 or the second corner area 125, the orthographic projection of the first touch line 311 on the base substrate 100 and the orthographic projection of the second touch line 312 on the base substrate 100 can also be arranged alternately.

As shown in FIG. 2, FIG. 5, FIG. 7 and FIG. 27, in this type of embodiment, the orthographic projections of the first touch line 311 and the second touch line 312 belonging to the same touch line 310 on the base substrate 100 overlap at least partially, and the first touch line 311 and the second touch line 312 whose orthographic projections on the base substrate 100 overlap are electrically connected one by one through the via holes of the first insulating layer 303 to transmit the same signal. For example, the first touch line 311 and the second touch line 312 are connected to form a first signal line, which can be connected to the first electrode group 330 for transmitting a driving signal. For another example, the first touch line 311 and the second touch line 312 are connected to form a second signal line, which can be connected to the second electrode group 331 for transmitting a detection signal. Of course, the first signal line can also be connected to the second electrode group 331 for transmitting a detection signal, and the second signal line can also be connected to the first electrode group 330 for transmitting a driving signal, which is not limited in the present disclosure.

In this type of embodiment, the first touch line 311 and the second touch line 312 are connected to each other for transmitting the same signal, and this scheme contributes to lowering the resistance and load. Further, in order to improve the stability of the connection between the first touch line 311 and the second touch line 312, the width of the overlapping area of the orthographic projection of the first touch line 311 and the orthographic projection of the second touch line 312 on the base substrate 100 belonging to the same touch line 310 is not less than 1.5 μm in the line width direction, so that the first touch line 311 and the second touch line 312 are connected by vias.

As shown in FIGS. 1 and 5 to 16, in some embodiments, the first touch line 311 and the second touch line 312 both include a first straight segment 313, a first connecting segment 314, a first curved segment 315, a second connecting segment 316 and a second straight segment 317 connected in sequence, the first straight segment 313 is located in the first straight area 121, the first connecting segment 314, the first curved segment 315 and the second connecting segment 316 are all located in the first corner area 124, and the second straight segment 317 is located in the second straight area 122; as shown in FIG. 15, along the direction from the second straight area 122 to the first corner area 124, the overlapping area of the orthographic projection of the second connecting segment 316 of the first touch line 311 on the base substrate 100 and the orthographic projection of the second connecting segment 316 of the correspondingly connected second touch line 312 on the base substrate 100 gradually decreases. That is, the second connecting segment 316 of the first touch line 311 and the second connecting segment 316 of the second touch line 312 are gradually misaligned along the direction from the second straight area 122 to the first corner area 124. The stacking diagram of the first straight segments 313 of the first touch line 311 and the second touch line 312 can be referred to FIG. 7, the stacking diagram of the first connecting segments 314 of the first touch line 311 and the second touch line 312 can be referred to FIG. 10, the stacking diagram of the first curved segments 315 of the first touch line 311 and the second touch line 312 can be referred to FIG. 13, and the stacking diagram of the second straight segments 317 of the first touch line 311 and the second touch line 312 can be referred to FIG. 16.

In the present disclosure, the first touch line 311 and the correspondingly connected second touch line 312 refer to the first touch line 311 and the second touch line 312 that transmit the same signal.

Further, the line width difference between the first touch line 311 and the second touch line 312 does not exceed 0.1 μm. The widths of the first touch line 311 and the second touch line 312 are substantially equal. The ratio of the overlapping area of the orthographic projection of the second straight segment 317 of the first touch line 311 and the orthographic projection of the second straight segment 317 of the second touch line 312 on the base substrate 100 to the area of the second straight segment 317 of the first touch line 311 or the area of the second straight segment 317 of the second touch line 312 is not less than 95%. That is, the second straight segment 317 of the first touch line 311 and the second straight segment 317 of the second touch line 312 are substantially overlapped.

In some embodiments, the line width of the first touch line 311 and the second touch line 312 is not less than 4.2 μm, wherein, as shown in FIG. 16, the second straight segment 317 of the first touch line 311 and the second straight segment 317 of the second touch line 312 are substantially completely overlapped, and the overlap width is the width of the touch line 310. As shown in FIG. 15, the overlap width of the second connecting segment 316 of the first touch line 311 and the second connecting segment 316 of the second touch line 312 is gradually reduced from the second straight area 122 to the first corner area 124, and the minimum overlap width is not less than 1.5 μm. The overlapping width of the first straight segment 313, the first connecting segment 314, the first curved segment 315 of the first touch line 311 and the first straight segment 313, the first connecting segment 314, the first curved segment 315 of the second touch line 312 is not less than 1.5 μm, and the first straight segment 313, the first connecting segment 314, the first curved segment 315 of the first touch line 311 and the first straight segment 313, the first connecting segment 314, the first curved segment 315 of the second touch line 312 do not completely overlap.

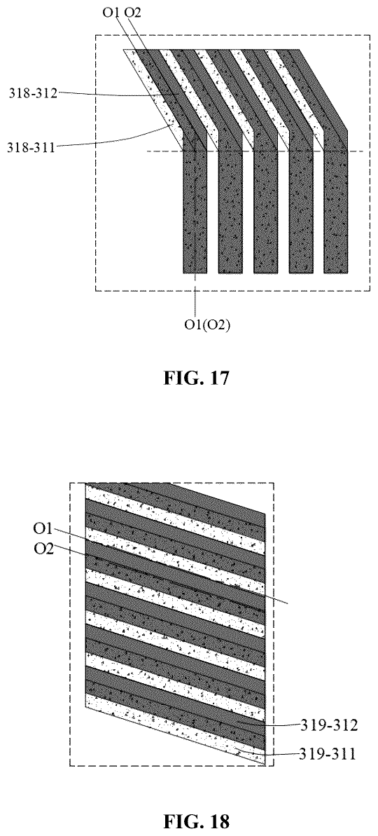

It is to be noted that the design scheme is also applicable to the first touch line 311 and the second touch line 312 located in the second corner area 125. As shown in FIG. 5 and FIG. 17 to FIG. 20, for example, the first touch line 311 and the second touch line 312 both further include a third connecting segment 318, a second curved segment 319, a fourth connecting segment 320 and a third straight segment 321, wherein the third connecting segment 318, the second curved segment 319 and the fourth connecting segment 320 are located in the second corner area 125, and the third straight segment 321 is located in the third straight area 123. As shown in FIG. 17, along the direction from the second straight area 122 to the second corner area 125, the overlapping area of the orthographic projection of the third connecting segment 318 of the first touch line 311 on the base substrate 100 and the orthographic projection of the third connecting segment 318 of the correspondingly connected second touch line 312 on the base substrate 100 gradually decreases. That is, the overlapping width of the third connecting segment 318 of the first touch line 311 and the third connecting segment 318 of the second touch line 312 gradually decreases along the direction from the second straight area 122 to the second corner area 125, and the minimum overlapping width is not less than 1.5 μm.

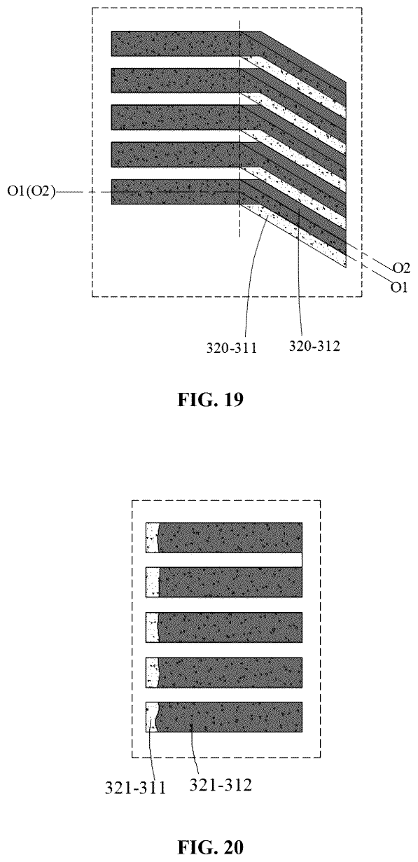

For the third straight segment 321 of the first touch line 311 and the third straight segment 321 of the second touch line 312, the two may be substantially completely overlapped or partially overlapped, and the width of the overlap is not less than 1.5 μm. When the third straight segment 321 of the first touch line 311 and the third straight segment 321 of the second touch line 312 substantially completely overlap, e.g., the ratio of the overlapping area to the area of the third straight segment 321 of the first touch line 311 or the area of the third straight segment 321 of the second touch line 312 is not less than 95% (as shown in FIG. 20), at this time, as shown in FIG. 19, along the direction from the third straight area 123 to the second corner area 125, the overlapping area of the orthographic projection of the fourth connecting segment 320 of the first touch line 311 on the base substrate 100 and the orthographic projection of the fourth connecting segment 320 of the correspondingly connected second touch line 312 on the base substrate 100 gradually decreases.

As shown in FIG. 2 and FIG. 5, in some other embodiments of the present disclosure, the touch line 310 is located in the second non-display area 126. In such embodiments, the opening area 130 divides at least one first electrode group 330 or at least one second electrode group 331 into two sub-electrode groups located on both sides of the opening area 130; the touch line 310 connects the two sub-electrode groups of the first electrode group 330 or the touch line 310 connects the two sub-electrode groups of the second electrode group 331; wherein the orthographic projections of the plurality of signal lines 210 located in the second non-display area 126 on the base substrate 100 at least partially overlap with the orthographic projections of the plurality of touch lines 310 on the base substrate 100.

In this type of embodiment, the first electrode group 330 includes a plurality of first electrodes 332, and two adjacent first electrodes 332 located in the display area 110 are connected by a first bridge line 334, and the second electrode group 331 includes a plurality of second electrodes 333, and two adjacent second electrodes 333 located in the display area 110 are connected by a second bridge line 335. Specifically, the first electrodes 332, the first bridge line 334, the second electrodes 333, and the second bridge line 335 can be distributed in different touch layers 300. For example, in one embodiment, the second bridge line 335 is distributed in the first touch layer 301, and the first electrodes 332, the first bridge line 334, and the second electrodes 333 are distributed in the second touch layer 302. In another embodiment, the first electrodes 332, the first bridge line 334, and the second electrode 333 are distributed in the first touch layer 301, and the second bridge line is distributed in the second touch layer 302.

In the opening area 130, the separated first electrode group 330 and the second electrode group 331 may be connected by the first touch line 311 and/or the second touch line 312.

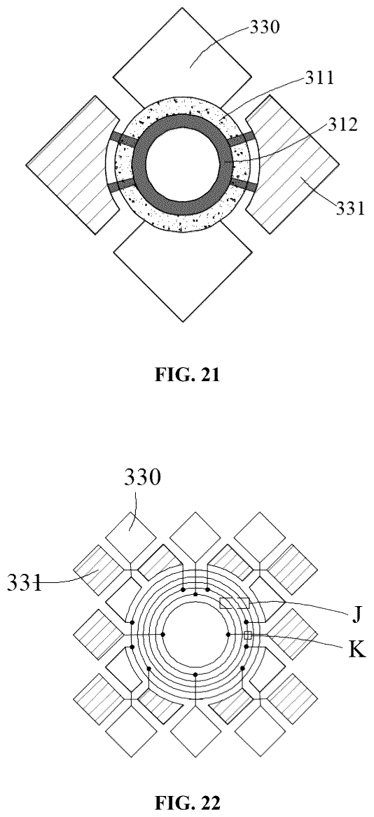

As shown in FIG. 2 and FIG. 21, in one embodiment, the opening area 130 divides a first electrode group 330 and a second electrode group 331 into two sub-electrode groups located on both sides of the opening area 130; the two sub-electrode groups of the first electrode group 330 are connected through the first touch line 311 or the second touch line 312; correspondingly, the two sub-electrode groups of the second electrode group 331 are connected through the second touch line 312 or the first touch line 311; the orthographic projections of the plurality of signal lines 210 located in the second non-display area 126 on the base substrate 100 are substantially located within the orthographic projections of the combination of the first touch line 311 and the second touch line 312 on the base substrate 100. In this embodiment, the size of the opening area 130 is generally smaller than the size of a first electrode 332 or a second electrode 333, and therefore, the opening area 130 separates a first electrode group 330 from a second electrode group 331. Meanwhile, in this embodiment, the first touch line 311 and the second touch line 312 are relatively wide, so as to cover a large area of the signal line 210 in the second non-display area 126. For example, the first touch line 311 is a whole conductive ring structure with a relatively wide width, or the second touch line 312 is a whole conductive ring structure with a relatively wide width, so as to cover the signal line 210 in the second non-display area 126.

As shown in FIGS. 2, 22 and 23, FIG. 23 is a schematic diagram of the arrangement of the first touch line 311 and the second touch line 312 in area I in FIG. 22. In another embodiment, the opening area 130 divides the plurality of first electrode groups 330 and the plurality of second electrode groups 331 into two sub-electrode groups located on both sides of the opening area 130. That is, in this embodiment, the opening area 130 is larger than the first electrode 332 and the second electrode 333, and the plurality of first electrode groups 330 and the plurality of second electrode groups 331 can be separated. The orthographic projections of the first touch line 311 and the second touch line 312 on the base substrate 100 at least partially overlap, and the first touch lines 311 and the second touch lines 312 whose orthographic projections on the base substrate 100 overlap are connected in one-to-one correspondence; as shown in FIG. 24, a part of the first touch lines 311 and the second touch lines 312 that are correspondingly connected are combined to form a first connection line 336, and a part of the first touch lines 311 and the second touch lines 312 that are correspondingly connected are combined to form a second connection line 337; the first connection line 336 connects the two sub-electrode groups of the first electrode group 330, the second connection line 337 connects the two sub-electrode groups of the second electrode group 331, and the first connection line 336 and the second connection line 337 are insulated. Specifically, the area where the first connection line 336 and the second connection line 337 intersect is a single-layer design. For example, at the position where the first connection line 336 and the second connection line 337 intersect, the first connection line 336 only includes the second touch line 312 in this area, and correspondingly the second connection line 337 only includes the first touch line 311 in this area. In this way, the insulation setting of the first connection line 336 and the second connection line 337 can be realized.

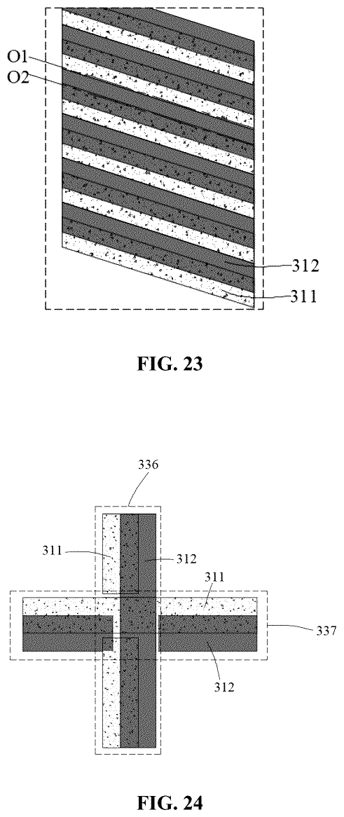

In this type of embodiment, as shown in FIG. 23, in at least part of the touch lines 310 in the second non-display area 126, the first touch line 311 and the second touch line 312 belonging to the same touch line 310 have a first center line O1 and a second center line O2, respectively, and in a direction perpendicular to the extension of the touch line 310, the first center line O1 and the second center line O2 are staggered. Further, the orthographic projection of the first touch line 311 and the orthographic projection of the second touch line 312 on the base substrate 100 of at least part of the touch lines 310 located in the second non-display area 126 are arranged alternately. That is, in the second non-display area 126, the arrangement of the first touch line 311 and the second touch line 312 is: the first touch line 311, the second touch line 312, the first touch line 311, the second touch line 312 . . . , and so on. The spacing between two adjacent first touch lines 311 is not less than 3 μm, and the spacing between two adjacent second touch lines 312 is not less than 3 μm, so as to avoid mutual interference of signal transmission. Furthermore, the width of the overlapping area of the orthographic projection of the first touch line 311 on the base substrate 100 and the orthographic projection of the second touch line 312 on the base substrate 100 in the line width direction is not less than 1.5 μm, so that the first touch line 311 and the second touch line 312 are connected by vias.

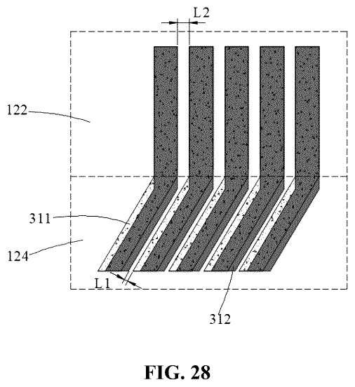

As shown in FIG. 1, FIG. 2, FIG. 5 and FIG. 28, in some embodiments of the present disclosure, the display panel provided by the present disclosure includes a base substrate 100, a signal line layer 200 and a touch layer 300. The base substrate 100 includes a display area 110 and a non-display area 120. The signal line layer 200 is disposed on a side of the base substrate 100, and the signal line layer 200 includes a plurality of signal lines 210, and the signal lines 210 are at least partially located in the non-display area 120. The touch layer 300 is disposed on a side of the signal line layer 200 away from the base substrate 100, and the touch layer 300 includes a plurality of touch lines 310, and the touch lines 310 are at least partially located in the non-display area 120. In the embodiment, the non-display area 120 includes a first non-display area, and the first non-display area is located at the periphery of the display area 110, and the orthographic projections of the plurality of touch lines 310 in the first non-display area on the base substrate 100 at least partially overlap with the orthographic projections of the plurality of signal lines 210 on the base substrate 100. In the first non-display area, there is a first gap L1 between the orthographic projections of two adjacent touch lines 310 on the base substrate 100, and there is a second gap L2 between the orthographic projections of two adjacent touch lines 310 in the non-display area 120 other than the first non-display area on the base substrate 100, and the first gap L1 is smaller than the second gap L2.

In this type of embodiment, the structural arrangement of the display area 110, the non-display area 120 and the first non-display area can refer to the above embodiment, and will not be described in detail here. For example, the first non-display area may include a first straight area 121, a first corner area 124, a third straight area 123 and a second corner area 125.

In some embodiments, the first gap L1 is 0.1 to 0.3 times the second gap L2.

In the first non-display area, the minimum distance between the orthographic projections of the first side and the fourth side of two adjacent touch lines 310 on the base substrate 100 is the first gap L1; in the non-display area 120 other than the first non-display area, the minimum distance between the orthographic projections of the first side and the fourth side of two adjacent touch lines 310 on the base substrate 100 is the second gap L2.

As shown in FIG. 28, in the first straight area 121, there is a first gap L1 between the orthographic projections of two adjacent touch lines 310 on the base substrate 100, and there is a second gap L2 between the orthographic projections of two adjacent touch lines 310 on the base substrate 100 in the second straight area 122, and the first gap L1 is smaller than the second gap L2.

The touch layer 300 includes a first touch layer 301 and a second touch layer 302 which are stacked, and a first insulating layer 303 arranged between the first touch layer 301 and the second touch layer 302. Each of the multiple touch lines 310 includes a first touch line 311 and a second touch line 312 connected in parallel. The first touch line 311 is distributed in the first touch layer 301, and the second touch line 312 is distributed in the second touch layer 302. In at least some of the touch lines 310, the orthographic projections of the first touch line 311 and the second touch line 312 belonging to the same touch line 310 on the base substrate 100 at least partially overlap.

The unit overlapping area between the first touch line 311 and the second touch line 312 in the first non-display area is smaller than the unit overlapping area between the first touch line 311 and the second touch line 312 in the non-display area 120 other than the first non-display area.

In the present disclosure, the unit overlapping area refers to the overlapping area of the first touch line 311 per unit area and the second touch line 312 per unit area.

In a specific embodiment, the first touch line 311 includes a first side and a second side that are arranged opposite to each other, and the second touch line 312 includes a third side and a fourth side that are arranged opposite to each other. In the first non-display area, the orthographic projection of the third side on the base substrate 100 is located between the orthographic projections of the first side and the second side on the base substrate 100, and the orthographic projection of the second side on the base substrate 100 is located between the orthographic projections of the third side and the fourth side on the base substrate 100.

As shown in FIG. 1, FIG. 2, FIG. 5, FIG. 7, FIG. 25, and FIG. 26, the present disclosure further provides a method for manufacturing a display panel, including:
Step S100, providing abase substrate 100, wherein the base substrate 100 includes a display area 110 and a non-display area 120;
Step S200, forming a signal line layer 200 on a side of the base substrate 100, wherein the signal line layer 200 includes a plurality of signal lines 210, and the signal lines 210 are at least partially located in the non-display area 120; and
Step S300, forming a touch layer 300 on a side of the signal line layer 200 away from the base substrate 100, wherein the touch layer 300 includes a plurality of touch lines 310, and the touch layer 300 includes a first touch layer 301 and a second touch layer 302 which are stacked, and a first insulating layer 303 which is disposed between the first touch layer 301 and the second touch layer 302, the touch lines 310 are at least partially located in the non-display area 120, the plurality of touch lines 310 include a plurality of first touch lines 311 and a plurality of second touch lines 312 which are stacked, the first touch lines 311 are distributed in the first touch layer 301, the second touch lines 312 are distributed in the second touch layer 302, and each of the touch lines 310 includes a first touch line 311 and a second touch line 312 which are connected in parallel.

The non-display area 120 includes a first non-display area, which is located at the periphery of the display area 110, and in the first non-display area, the orthographic projections of the plurality of touch lines 310 on the base substrate 100 at least partially overlap with the orthographic projections of the plurality of signal lines 210 on the base substrate 100. In at least part of the touch lines 310 in the first non-display area, the first touch line 311 and the second touch line 312 belonging to the same touch line 310 respectively have a first center line O1 and a second center line O2, and in a direction perpendicular to the extension of the touch line 310, the first center line O1 and the second center line O2 are not aligned.

In step S100, the non-display area 120 may include a plurality of areas. In some embodiments of the present disclosure, the non-display area 120 is located at the periphery of the display area 110, and the non-display area 120 includes a first non-display area, which is located at the periphery of the display area 110. The non-display area 120 also includes a second straight area 122, which is located at least on one side of the display area 110 in the second direction X, and the first non-display area includes a first straight area 121 and a first corner area 124. The first straight area 121 is located on one side of the display area 110 in the first direction Y; the first corner area 124 connects the first straight area 121 and the second straight area 122. The non-display area 120 also includes a binding area 17, which is located on one side of the first straight area 121 away from the display area 110. Furthermore, the first non-display area also includes a third straight area 123 and a second corner area 125. The third straight area 123 is located on a side of the display area 110 away from the first straight area 121. The second corner area 125 connects the second straight area 122 and the third straight area 123.

In some embodiments of the present disclosure, the base substrate 100 further includes an opening area 130, which is located in the display area 110. The display panel further includes a second non-display area 126 located between the opening area 130 and the display area 110. The non-display area 120 further includes the second non-display area 126.

In step S200, the signal lines 210 are arranged relatively densely in the formed signal line layer 200, and the material of the signal line 210 includes a metal material with strong light reflection ability, such as metal molybdenum (Mo). The formed signal line layer 200 can be multi-layered, such as forming a first metal layer and a second metal layer which are stacked, and the signal lines 210 in the first metal layer and the signal lines 210 in the second metal layer are arranged relatively densely.

In step S300, the formed touch layer 300 may include two layers, namely a first touch layer 301 and a second touch layer 302. The light reflectivity of the first touch layer 301 and the second touch layer 302 is lower than the light reflectivity of the signal line layer 200. Specifically, the light reflectivity of the touch layer 300 may be adjusted by adjusting the material and formation process of the touch layer 300.

In one embodiment, the materials of the first touch layer 301 and the second touch layer 302 may include titanium (Ti) and aluminum (Al), and the first touch layer 301 and the second touch layer 302 may both be multi-layer stacked structures, such as the structure of the first touch layer 301 and the second touch layer 302 is titanium (Ti)-aluminum (Al)-titanium (Ti), that is, a titanium (Ti) metal layer, an aluminum (Al) metal layer and a titanium (Ti) metal layer are stacked. Further, the formation temperature of the first touch layer 301 and the second touch layer 302 is not higher than 85° C., so that a touch layer 300 with low light reflection ability can be formed. Specifically, a titanium metal layer can be first formed by evaporation on the side of the signal line layer 200 away from the base substrate, and then an aluminum metal layer can be formed by evaporation on the side of the titanium metal layer away from the base substrate, and then a titanium metal layer is formed again on the side of the aluminum metal layer away from the base substrate, and the temperature does not exceed 85° C. during the whole process.

The plurality of touch lines 310 may include a plurality of first touch lines 311 and a plurality of second touch lines 312. The first touch lines 311 may be distributed in the first touch layer 301, and the second touch lines 312 may be distributed in the second touch layer 302. The touch lines 310 may be located in different regions of the base substrate 100, and the touch lines 310 in different regions may be arranged differently. Specifically, the touch lines 310 with specific patterns in the region may be formed by performing different patterning in different regions. For example, a first touch material layer may be formed on a side of the signal line layer 200 away from the base substrate 100, and then the touch material layer may be patterned to form a first touch layer 301 including the first touch lines 311, and then a second touch material layer may be formed on a side of the first touch layer 30 away from the base substrate 100, and then the touch material layer may be patterned to form a second touch layer 302 including the second touch lines 312. The patterns of the first touch lines 301 and the second touch lines 302 formed in different regions may be different. The specific pattern may be changed according to the arrangement of the signal lines 210 in the region. For example, as shown in FIG. 5, FIG. 7, FIG. 10 and FIG. 13, the patterns of the first touch lines 301 and the second touch lines 302 are formed so that in the first straight area 121 or the first corner area 124, the orthographic projections of the plurality of signal lines 210 on the base substrate 100 are located within the orthographic projections of the combination of the plurality of first touch lines 311 and the plurality of second touch lines 312 on the base substrate 100. Also, the orthographic projections of the first touch lines 301 and the second touch lines 302 formed by at least part of the touch lines 310 on the base substrate 100 are arranged alternately. That is, in the first straight area 121 and the first corner area 124, the first touch lines 311 and the second touch lines 312 are arranged in the following order: a first touch line 311, a second touch line 312, a first touch line 311, a second touch line 312 . . . , and so on.

In the display panel manufactured by the manufacturing method of the display panel provided by the present disclosure, the touch layer 300 has a lower light reflectivity than the signal line layer 200, and at least part of the multiple touch lines 310 located in the non-display area 120 can cover the multiple signal lines 210 located in the area. In this way, the reflection of light by the signal lines 210 in the area can be reduced, thereby preventing the area from reflecting light under strong light and affecting the display quality.

Furthermore, when the touch layer 300 is manufactured, the touch layer 300 is a stacked conductive layer including a titanium metal layer, an aluminum metal layer and a titanium metal layer, and the formation process does not exceed 85° C. Under this condition, a touch layer 300 with lower light reflectivity can be formed, thereby helping to better reduce the light reflectivity of the signal line layer 210.

The present disclosure also provides a display device, including a display panel, which can be a display panel of any of the above embodiments, and its specific structure and beneficial effects can refer to the embodiments of the display panel above, which will not be repeated here. The display device of the present disclosure can be an electronic device such as a mobile phone, a tablet computer, a television, etc., which will not be listed one by one here.

It should be noted that, although the steps of the method in the present disclosure are described in a specific order in the drawings, this does not require or imply that the steps must be performed in the specific order, or that all the steps shown must be performed to achieve the desired results. Additionally or alternatively, some steps may be omitted, multiple steps may be combined into one step, and/or one step may be divided into multiple steps, etc., which shall all be considered as part of the present disclosure.

It should be understood that the present disclosure does not limit its application to the detailed structure and arrangement of the components proposed in this specification. The present disclosure can have other embodiments and can be implemented and executed in a variety of ways. The aforementioned variations and modifications fall within the scope of the present disclosure. It should be understood that the present disclosure disclosed and defined in this specification extends to all alternative combinations of two or more individual features mentioned or evident in the text and/or the drawings. All these different combinations constitute multiple alternative aspects of the present disclosure. The embodiments of this specification illustrate the best mode known for implementing the present disclosure and will enable those skilled in the art to utilize the present disclosure.

1. A display panel, comprising:
a base substrate, comprising a display area and a non-display area;
a signal line layer, disposed on a side of the base substrate, the signal line layer comprising a plurality of signal lines, and the signal lines are at least partially located in the non-display area; and
a touch layer, disposed on a side of the signal line layer away from the base substrate, wherein the touch layer comprises a plurality of touch lines, and the touch layer comprises a first touch layer and a second touch layer arranged in a stacked manner, and a first insulating layer disposed between the first touch layer and the second touch layer, the touch lines are at least partially located in the non-display area, the plurality of touch lines comprise a plurality of first touch lines and a plurality of second touch lines arranged in a stacked manner, the first touch lines are disposed in the first touch layer, the second touch lines are disposed in the second touch layer, and each of the touch lines comprises a first touch line and a second touch line connected in parallel;
wherein, the non-display area comprises a first non-display area, the first non-display area is located at a periphery of the display area, and orthographic projections of the plurality of touch lines in the first non-display area on the base substrate at least partially overlap with orthographic projections of the plurality of signal lines on the base substrate;
in at least part of the touch lines within the first non-display area, the first touch line and the second touch line belonging to a same touch line respectively have a first center line and a second center line, and the first center line and the second center line are not aligned in a direction perpendicular to the extension of the touch line.

2. The display panel according to claim 1, wherein orthographic projections on the base substrate of at least part of the plurality of signal lines located in the non-display area are located within an orthographic projection on the base substrate of a combination of at least one of the first touch lines and at least one of the second touch lines.

3. The display panel according to claim 1, wherein orthographic projections of the first touch line and the second touch line belonging to the same touch line on the base substrate at least partially overlap, and the first touch line and the second touch line whose orthographic projections on the base substrate overlap are electrically connected through a via in the first insulating layer in one-to-one correspondence.

4. The display panel according to claim 3, wherein a width in a line width direction, of an overlapping area of an orthographic projection of the first touch line and an orthographic projection of the second touch line on the base substrate belonging to the same touch line, is not less than 1.5 μm.

5. The display panel according to claim 3, wherein the non-display area further comprises a second straight area, and the second straight area is located at one side of the display area in the second direction; and
the first non-display area comprises:
a first straight area, located at one side of the display area in the first direction; and
a first corner area, connecting the first straight area and the second straight area;
wherein, orthographic projections of the first touch lines on the base substrate and the orthographic projections of the second touch lines on the base substrate of at least part of the touch lines located in the first straight area or the first corner area are arranged alternately.

6. The display panel according to claim 5, wherein the first non-display area further comprises:
a third straight area, disposed at a side of the display area away from the first straight area; and
a second corner area, connecting the second straight area and the third straight area;
wherein, the orthographic projections of the first touch lines on the base substrate and the orthographic projections of the second touch lines on the base substrate of at least part of the touch lines located in the third straight area or the second corner area are arranged alternately.

7. The display panel according to claim 5, wherein the first touch line and the second touch line each comprise a first straight segment, a first connecting segment, a first curved segment, a second connecting segment and a second straight segment connected in sequence, the first straight segment is located in the first straight area, the first connecting segment, the first curved segment and the second connecting segment are all located in the first corner area, and the second straight segment is located in the second straight area;
along a direction from the second straight area to the first corner area, an overlapping area of an orthographic projection of the second connecting segment of the first touch line on the base substrate and an orthographic projection of the corresponding second connecting segment of the second touch line on the base substrate gradually decreases.

8. The display panel according to claim 6, wherein the first touch line and the second touch line each further comprise a third connecting segment, a second curved segment, a fourth connecting segment and a third straight segment connected in sequence, the third connecting segment, the second curved segment and the fourth connecting segment are all located in the second corner area, and the third straight segment is located in the third straight area;
along a direction from the second straight area to the second corner area, an overlapping area of an orthographic projection of the third connecting segment of the first touch line on the base substrate and an orthographic projection of the corresponding third connecting segment of the second touch line on the base substrate gradually decreases.

9. The display panel according to claim 7, wherein a ratio of an overlapping area of an orthographic projection of the second straight segment of the first touch line on the base substrate and an orthographic projection of the second straight segment of the second touch line on the base substrate to an area of the second straight segment of the first touch line or an area of the second straight segment of the second touch line is not less than 95%.

10. The display panel according to claim 1, wherein the base substrate further comprises an opening area, the opening area is located in the display area, and the non-display area further comprises a second non-display area located between the opening area and the display area;
the touch layer further comprises a plurality of touch electrodes, the plurality of touch electrodes comprise a plurality of first electrode groups extending along a first direction and a plurality of second electrode groups extending along a second direction, and the first electrode groups and the second electrode groups are insulated from each other;
at least one of the first electrode groups and at least one of the second electrode groups are divided by the opening area into two sub-electrode groups located on both sides of the opening area;
the touch line is connected to the two sub-electrode groups of the first electrode group or the touch line is connected to the two sub-electrode groups of the second electrode group;
wherein, orthographic projections of the plurality of touch lines in the second non-display area on the base substrate at least partially overlap with orthographic projections of the plurality of signal lines on the base substrate;
in at least part of the touch lines within the second non-display area, the first touch line and the second touch line belonging to a same touch line respectively have a first center line and a second center line, and the first center line and the second center line are not aligned in a direction perpendicular to the extension of the touch line.

11. The display panel according to claim 10, wherein orthographic projections of the first touch lines on the base substrate and orthographic projections of the second touch lines on the base substrate of at least part of the touch lines located in the second non-display area are arranged alternately.

12. The display panel according to claim 1, wherein a line width of the first touch line and the second touch line is not less than 4.2 μm; a spacing between two adjacent first touch lines is not less than 3 μm; and a spacing between two adjacent second touch lines is not less than 3 μm.

13. (canceled)

14. A display panel, comprising:
a base substrate, comprising a display area and a non-display area;
a signal line layer, disposed on a side of the base substrate, the signal line layer comprising a plurality of signal lines, and the signal lines are at least partially located in the non-display area; and
a touch layer, disposed on a side of the signal line layer away from the base substrate, the touch layer comprising a plurality of touch lines, and the touch lines are at least partially located in the non-display area;
the non-display area comprises a first non-display area, the first non-display area is located at a periphery of the display area, and orthographic projections of the plurality of touch lines in the first non-display area on the base substrate at least partially overlap with orthographic projections of the plurality of signal lines on the base substrate;
in the first non-display area, the first gap is between orthographic projections of two adjacent touch lines on the base substrate, and the second gap is between orthographic projections of two adjacent touch lines in the non-display area other than the first non-display area on the base substrate, and the first gap is smaller than the second gap.

15. The display panel according to claim 14, wherein the touch layer comprises a first touch layer and a second touch layer arranged in a stacked manner, and a first insulating layer disposed between the first touch layer and the second touch layer, each of the plurality of touch lines comprises a first touch line and a second touch line connected in parallel, the first touch line is disposed in the first touch layer, and the second touch line is disposed in the second touch layer; and among at least some of the touch lines, orthographic projections of the first touch line and the second touch line belonging to the same touch line on the base substrate at least partially overlap,
a unit overlapping area between the first touch line and the second touch line in the first non-display area is smaller than a unit overlapping area between the first touch line and the second touch line in a non-display area other than the first non-display area.

16. The display panel according to claim 15, wherein the first touch line comprises a first side and a second side that are oppositely disposed, and the second touch line comprises a third side and a fourth side that are oppositely disposed;
in the first non-display area, an orthographic projection of the third side on the base substrate is located between orthographic projections of the first side and the second side on the base substrate, and the orthographic projection of the second side on the base substrate is located between orthographic projections of the third side and the fourth side on the base substrate.

17. The display panel according to claim 16, wherein, in the first non-display area, a minimum distance between the orthographic projections of a first side and a fourth side of two adjacent touch lines on the base substrate is the first gap; and
in the non-display area except the first non-display area, the minimum distance between the orthographic projections of the first side and the fourth side of two adjacent touch lines on the base substrate is the second gap.

18. The display panel according to claim 14, wherein the first gap is 0.1 to 0.3 times the second gap.

19. A method for manufacturing display panel, comprising:
providing a base substrate, the base substrate comprising a display area and a non-display area;
forming a signal line layer on a side of the base substrate, wherein the signal line layer comprises a plurality of signal lines, and at least part of the signal lines are located in the non-display area; and
forming a touch layer on a side of the signal line layer away from the base substrate, wherein the touch layer comprises a plurality of touch lines, and the touch layer comprises a first touch layer and a second touch layer arranged in a stacked manner, and a first insulating layer disposed between the first touch layer and the second touch layer, the touch lines are at least partially located in the non-display area, the plurality of touch lines comprise a plurality of first touch lines and a plurality of second touch lines arranged in a stacked manner, the first touch lines are disposed in the first touch layer, the second touch lines are disposed in the second touch layer, and each of the touch lines comprises a first touch line and a second touch line connected in parallel;
wherein, the non-display area comprises a first non-display area, the first non-display area is located at a periphery of the display area, and orthographic projections of the plurality of touch lines in the first non-display area on the base substrate at least partially overlap with orthographic projections of the plurality of signal lines on the base substrate;
in at least part of the touch lines within the first non-display area, the first touch line and the second touch line belonging to a same touch line respectively have a first center line and a second center line, and the first center line and the second center line are not aligned in a direction perpendicular to the extension of the touch line.

20. The method for manufacturing display panel according to claim 19, wherein a material of the touch layer comprises titanium and aluminum, and the formation temperature of the touch layer does not exceed 85° C.

21. A display device, comprising a display panel according to claim 1.
